(19) United States
(12) Patent Application Publication
(10) Pub. No.: US 2008/0204056 A1
(43) Pub. Date: Aug. 28, 2008

(54) DEVICE AND METHOD FOR PERFORMING A TEST OF SEMICONDUCTOR DEVICES WITH AN OPTICAL INTERFACE

(75) Inventors: Wolfgang Spirkl, Germering (DE); Holger Steffens, Muenchen (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: QIMONDA AG, Muenchen (DE)

(21) Appl. No.: 12/039,133

(22) Filed: Feb. 28, 2008

(30) Foreign Application Priority Data
Feb. 28, 2007 (DE) 10 2007 009 878.4

(51) Int. Cl. G01R 31/302

(52) U.S. Cl. 324/750

(57) ABSTRACT

A device and method for performing a test of semiconductor devices with an optical interface. In one embodiment, the device performs a test at a semiconductor device with an integrated self test function and with an optical interface. An optical transmitter and an optical receiver provide a system configured for returning an optical emission of the semiconductor device from the optical transmitter to the optical receiver of the semiconductor device.

### CROSS-REFERENCE TO RELATED APPLICATIONS

This Utility patent application claims priority to German Patent Application No. DE 10 2007 009 878.4 filed on Feb. 28, 2007, which is incorporated herein by reference.

### BACKGROUND

The invention relates to a device, a system, and a method for performing a test of semiconductor devices with an optical interface, in one embodiment of semiconductor memory devices.

Semiconductor devices, e.g., integrated (analog or digital) computing circuits, semiconductor memory devices such as, for instance, functional memory devices (PLAs, PALs, etc.) and table memory devices (e.g., ROMs or RAMs, in one embodiment SRAMs and DRAMs), etc. are subject to comprehensive tests during and after their manufacturing processes.

For the common manufacturing of a plurality of (in general identical) semiconductor devices, a wafer (i.e. a thin disc of monocrystalline silicon) is used. The wafer is processed appropriately (e.g., subject successively to a plurality of coating, exposure, etching, diffusion, and implantation processes, etc.), and subsequently e.g., sawn apart (or e.g., scratched, and broken), so that the individual devices are then available.

During the above-mentioned manufacturing process and after the finishing of the semiconductor devices (i.e. after the performing of all the above-mentioned wafer processes), the semiconductor devices are i.a. subject to a plurality of test methods—for instance, it is possible to test the finished devices that are still available on the wafer by using appropriate test devices (“wafer tests”).

In one embodiment, one or a plurality of further tests (at further test stations, and by using appropriate, further test devices) may, for instance, be performed after the incorporation of the semiconductor devices in the semiconductor device packages, and/or, for instance, after the incorporation of the semiconductor device packages (along with the respectively incorporated semiconductor devices) in electronic modules, e.g., memory modules (“module tests”).

For a cost-efficient manufacturing of semiconductor devices it is required that both the costs for the manufacturing of the semiconductor devices and the costs for the testing of the semiconductor devices are reduced. Due to the strongly increased complexity of the semiconductor devices, the costs for the testing of the devices are in many cases comparable to the costs for the manufacturing of the dies in the manufacturing facility. The test effort is i.a. dependent on the costs for the test equipment and on the test time in which the test equipment is used for the testing of the semiconductor devices. It is therefore desirable to minimize both the test time and the complexity of the test equipment so as to minimize the costs for the testing of the semiconductor devices.

For avoiding excessive costs with a simultaneous adequate provision against errors, the development has recently gone toward semiconductor devices or integrated circuits, respectively, with an integrated self test function (Built-in Self Test, BIST). With this proceeding, one or a plurality of circuits are implemented in the semiconductor device or in the integrated circuit itself, which enable a self test. The respective integrated test circuit generates test signals and may then compare, for instance, response signals that were generated in reaction to the test signals with predetermined correct response signals, so that a test result can be output to an assigned Automatic Test Equipment (ATE). Built-in Self Tests are increasingly simple to implement by automated design processes and consume relatively little space with the large number of circuit elements that is common nowadays, but they are adapted to substantially reduce the material and time effort during testing.

The above-described Built-in Self Test function is usually implemented in conventional semiconductor devices with an electrical interface, but it may also be used and implemented in semiconductor devices with an optical interface.

Semiconductor devices with an optical interface will gain increasing importance in the future since it is to be expected that the clock frequencies of future processors, etc. will continue to expand in the range of several Gigabits per second and more, and since sophisticated information processing systems will thus require total bandwidths of up to 1 Terabit per second and more for data communication. The previously common connecting medium, copper lines, will no longer be suited for such bandwidths.

It is therefore to be assumed that optical media will find a broad range of application in high performance systems, and that optical media will replace the previously common electrical media in many fields. Thus, optical connections for the data communication between individual devices, modules, but also between semiconductor devices on the same printed circuit board or in the same module are conceivable in the nearer future. The bandwidth of data communication between a GPU (Graphic Processor Unit) and an assigned memory is, for instance, continually increasing to such a degree that an (at least partial) optical interface between the GPU and the memory will replace the present electrical interface in the nearer future.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 illustrates an exemplary simplified schematic representation of a system with two semiconductor devices communicating via an optical connection.

FIG. 2 illustrates a simplified schematic representation of a system according to one embodiment.

FIG. 3 illustrates a simplified schematic representation of a system according to one embodiment.

FIG. 4 illustrates a simplified schematic representation of a system according to one embodiment.

FIG. 5 illustrates a simplified schematic representation of a system according to one embodiment.

FIG. 6 illustrates a simplified schematic representation of a system according to one embodiment.

FIG. 7 illustrates a simplified schematic representation of a system according to one embodiment.

FIG. 8 illustrates a simplified schematic representation of a system according to one embodiment.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

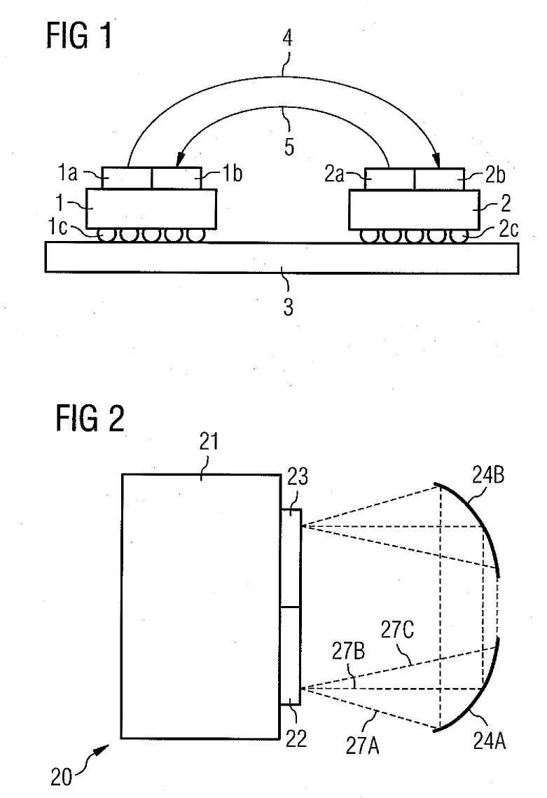

FIG. 1 illustrates a typical system arrangement in which two semiconductor devices 1, 2 (e.g., a GPU and a memory device) are connected via an optical interface. Additionally, the two semiconductor devices are connected with the system PCB (Printed Circuit Board) 3 via an electrical interface or an electrical connection. Both semiconductor devices include an optical transmitter 1A, 2A, for instance, a laser diode, and an optical receiver 1B, 2B, for instance, a photo diode. The optical transmitter 1A, 2A of the one semiconductor device is connected with the respective optical receiver 1B, 2B of the other semiconductor device via optical high speed connections 4, 5.

The testing of such semiconductor devices with an optical interface by using an external, optical ATE is complex and cost-intensive since an expensive high speed test equipment has to be used. Additionally, a control for the automatic connection of the optical output of the semiconductor device to be tested with the ATE is required. Further, a parallel testing of a plurality of semiconductor devices is possible in a restricted scope only since an optical connection to the external optical ATE is required for every semiconductor device to be tested.

One or more embodiments provide a device and a method for performing a self test at a semiconductor device with an integrated self test function, in one embodiment a device and a method which require, with adequate provision against errors, less time and cost efforts for a testing of semiconductor devices with an optical interface.

In one embodiment, there is provided a device for performing a test at a semiconductor device with an integrated self test function and with an optical interface which includes an optical transmitter and an optical receiver, wherein the device includes a system or means for returning an optical emission of the semiconductor device from the optical transmitter to the optical receiver of the semiconductor device.

In one embodiment, there is provided a system for performing a test which includes a semiconductor device with an integrated self test function and with an optical interface, wherein the optical interface includes an optical input and an optical output, wherein the system further includes a system or means for returning an optical emission of the semiconductor device from the optical output of the semiconductor device to the optical input of the semiconductor device.

In one embodiment, there is provided a method for performing a test at a semiconductor device with an integrated self test function and with an optical interface which includes an optical input and an optical output, wherein an optical emission of the semiconductor device is returned from the optical output to the optical input of the semiconductor device.

The embodiments have in common that a semiconductor device with an optical interface and an integrated self test function, the Built-in Self Test (BIST) functionality, has to be tested in each case.

In the following embodiments, as will be explained in more detail in the following, a BIST logic provided on the respective device may, for instance, generate test signals or test patterns, i.e., for instance, a plurality of test input signals for partial circuits of the semiconductor device to be tested, and/or the optical interface, and output the test response signals generated by the respective partial circuits and/or the optical interface in response to the test input signals, and/or compare them with predetermined test response signals.

By using the optical interface, the semiconductor device is configured to communicate via an optical high speed line with, for instance, other semiconductor devices.

Therefore, conventional test method by using an external automatic test equipment, the Automatic Test Equipment (ATE), require a relatively expensive optical high speed ATE for a test of the semiconductor device which includes a testing of the optical interface.

In the present embodiments, the requirement of the expensive optical high speed ATE may be eliminated in that the above-mentioned test input signals or the test response signals generated in reaction thereto which are output by an optical transmitter of the semiconductor device as optical signals may be returned to an optical receiver of the semiconductor device via suitable means for returning these optical signals, be converted to electrical signals by the optical receiver, and be then compared, for instance, by the BIST logic with predetermined test response signals.

This proceeding can thus also have the further advantage that the optical transmitter and the optical receiver of the semiconductor device to be tested are tested simultaneously.

FIG. 2 illustrates as simplified schematic representation of a system according to one embodiment.

The system 20 illustrated in FIG. 2 includes a semiconductor device 21 with an optical transmitter 22 and an optical receiver 23, and a spherical reflector 24A, 24B. The optical transmitter may, for instance, be designed as a laser diode such as, for instance, a SCH (Separate Confinement Hetero Structure) laser diode or a VCSEL (Vertical Cavity Surface Emitting Laser) diode.

The spherical reflector 24A, 24B is suited to reflect the electromagnetic beams or light beams, respectively, emitted by the optical transmitter 22. In the drawing, three exemplary optical paths 27A, 27B, 27C of the plurality of possible optical paths of the light radiation are illustrated. The drawing plane constitutes a two-dimensional cross-section through the three-dimensional radiation cone and the three-dimensional spherical reflector 24A, 24B. The two outer optical paths 27A and 27C quasi span the radiation cone emitted by the optical transmitter 22. As may be seen, the illustrated spherical reflector 24A, 24B is suited to reflect light radiation with a high divergence such that the broad radiation cone is bundled prior to hitting the optical receiver 23, or that the beams are oriented in parallel, respectively, and thus a large portion of the strongly divergent radiation emitted by the transmitter 22 is detected by the receiver 23.

An even more efficient returning of the radiation with high divergence emitted by the transmitter 22 can be achieved in that the principles of non-imaging optics are used when designing the spherical reflector 24A, 24B, i.e. all beams of the entire radiation cone are considered and taken into account during the designing of the spherical reflector 24A, 24B such that substantially all light beams, i.e. optical paths of the radiation cone emitted by the optical transmitter 22, are reflected on the optical receiver 23 in a bundled manner, and that it substantially detects all the beams emitted by the transmitter 22. The principles of non-imaging optics are described for three-dimensional problems, for instance, in H. Ries and J. Muschawek: “Tailored freeform optical surfaces”, Journal Optical Society of America A, volume 19, pages 590-595, March 2002, Optical Society of America.

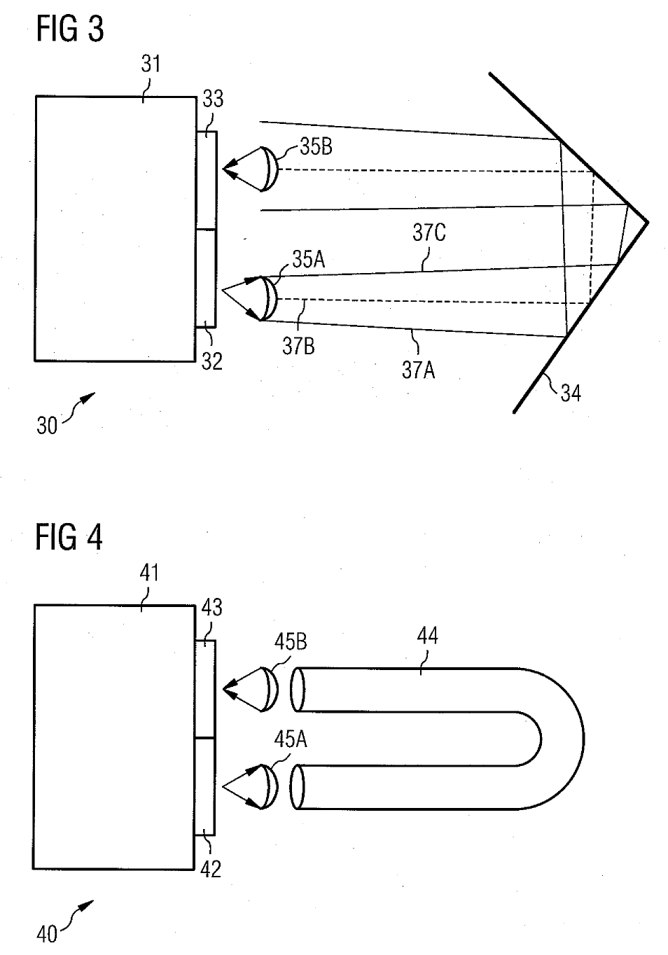

FIG. 3 illustrates a simplified schematic representation of a system according to one embodiment.

The system 30 illustrated in FIG. 3 includes a semiconductor device 31 with an optical transmitter 32, for instance, a laser diode, and with an optical receiver 33, for instance, a photo diode, and a rear reflector 34.

The rear reflector 34 is suited to reflect the radiation emitted by the transmitter 32. The rear reflector 34 consists of three essentially planar reflectors, for instance, mirrors which form a right angle together.

The radiation cone emitted by the optical transmitter 32, indicated by the three exemplary optical paths 37A, 37B, 37C, is reflected via the rear reflector 34 back to the receiver 33 of the semiconductor device 31. As is illustrated in FIG. 3 by using the exemplary optical paths 37A, 37B, 37C, the radiation cone is not collimated, i.e. oriented in parallel, by the rear reflector, but is merely reflected. Thus, only for a radiation emitted by the optical transmitter 32 which has a low divergence is it ensured that a substantial portion of the radiation is reflected back to the receiver 33 of the semiconductor device 31.

In one embodiment, the illustrated system 30 includes two optical lenses 35A and 35B, wherein the optical lens 35A collimates, i.e. orients in parallel, the beams emitted by the transmitter 32, and the optical lens 35B focuses the beam reflected back in the direction of the semiconductor device 31 on the optical receiver 33. For a radiation with low divergence emitted by the optical transmitter 32, the portion of the radiation emitted by the optical transmitter which is detected by the optical receiver 33 can be distinctly increased by using the two optical lenses 35A and 35B.

FIG. 4 illustrates a simplified schematic representation of a system according to one embodiment.

The illustrated system 40 includes a semiconductor device 41 with an optical transmitter 42 and an optical receiver 43, a fiber optic cable 44, and two optical lenses 45A and 45B.

The radiation emitted by the optical transmitter 42 is collimated by using the optical lens 45a, enters the fiber optic cable 44, and is guided along the fiber optic cable 44. The radiation emanating from the fiber optic cable 44 is focused on the optical receiver 43 by the optical lens 45B, so that the major portion of the radiation emitted by the transmitter 42 is detected at the receiver 43.

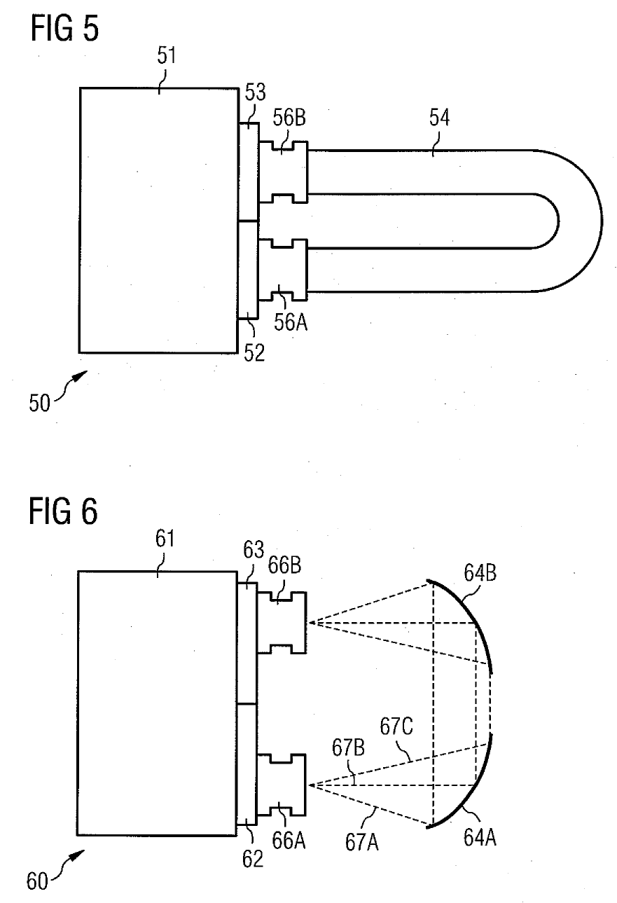

FIG. 5 illustrates a simplified schematic representation of a system according to one embodiment.

The illustrated system 50 includes a semiconductor device 51 with an optical transmitter 52, an optical receiver 53, a first connection 56A for fiber optic cables, and a second connection 56B for fiber optic cables, and a fiber optic cable 54.

The optical transmitter 52 is connected with the first connection 56A for fiber optic cables, and the optical receiver 53 is connected with the second connection 56B for fiber optic cables. The fiber optic cable 54 is connected with its ends with the first connection 56A for fiber optic cables and with the second connection 56B for fiber optic cables. Thus, the optical signal or the radiation, respectively, generated in the optical transmitter 52 is, via the first connection 56A for fiber optic cables, directly guided into the fiber optic cable 54 that guides the optical signal or the radiation, respectively, via the second connection 56B for fiber optic cables, directly to the optical receiver 53 that detects the optical signal.

FIG. 6 illustrates a simplified schematic representation of a system according to one embodiment.

The system 60 illustrated in FIG. 6 includes a semiconductor device 61 with an optical transmitter 62, an optical receiver 63, a first connection 66A for fiber optic cables, and a second connection 66B for fiber optic cables, and a spherical reflector 64A, 64B that is suited to reflect the radiation emitted by the transmitter 62.

The embodiment illustrated in FIG. 6 corresponds to the embodiment illustrated in FIG. 2, with the exception that the optical signal or the radiation, respectively, generated by the optical transmitter 62 emanates from the first connection 66A for fiber optic cables and, after a suitable reflection at the spherical reflector 64A, 64B in analogy to the reflection at the spherical reflector 24A, 24B illustrated in FIG. 2, enters the second connection 66B for fiber optic cables, and is guided to the optical receiver.

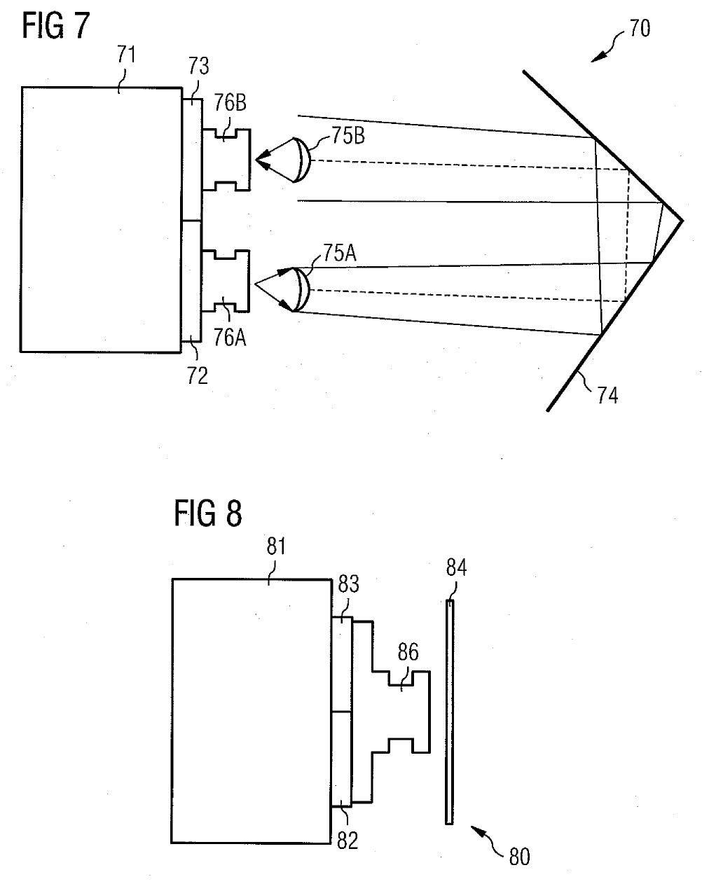

FIG. 7 illustrates a simplified schematic representation of a system according to one embodiment.

In the embodiment illustrated in FIG. 7, the spherical reflector 64A, 64B of FIG. 6 is replaced by a rear reflector 74. Otherwise, one embodiment illustrated in FIG. 7 is in analogy to the embodiment illustrated in FIG. 6.

Like the embodiment with a rear reflector illustrated in FIG. 3, one embodiment illustrated in FIG. 7 is, for analogous reasons, suited in one embodiment for a returning of radiation with low divergence.

One embodiment illustrated in FIG. 7 includes a first optical lens 75A and a second optical lens 75B, wherein the first optical lens 75A collimates the light beam emanating from the first connection 76A for fiber optic cables, and the second optical lens 76B focuses the light beam reflected by the rear reflector 74 on the second connection for fiber optic cables 76B. By using the two optical lenses 75A and 75B, the portion of the radiation emitted by the optical transmitter 72 which is detected by the receiver 73 is increased.

In the previous embodiments of the systems illustrated in FIG. 2 to FIG. 7, it was assumed tacitly that the respective optical transmitters and receivers transmit or receive at the same frequency. If this should not be the case, the frequency of the optical signal emitted by the optical transmitter has to be shifted to the frequency at which the respective receiver receives optical signals. For this case, the respective systems 20, 30, 40, 50, 60, or 70 expediently include a system, mechanism or means for changing the frequency of the optical signal emitted by the respective optical transmitter, which are arranged in a suitable place in the system.

FIG. 8 illustrates a simplified schematic representation of a system according to one embodiment.

The system 80 illustrated in FIG. 8 includes a semiconductor device 81 with an optical transmitter 82, an optical receiver 83, and a connection 86 for a bi-directional fiber optic cable, and a substantially planar reflector 84 or mirror, respectively.

The connection 86 for a bi-directional fiber optic cable is connected both with the optical transmitter 82 and with the optical receiver 83, and is suited, on the one hand, to guide optical signals from the transmitter 82 to its input/output and, on the other hand, to guide incoming optical signals from its input/output to the receiver 83.

The substantially planar reflector 84 is positioned close to the input/output of the connection 86 for a bi-directional fiber optic cable, so that an optical signal or radiation, respectively, emanating from the connection 86 is reflected directly back to the input/output of the connection 86 at the substantially planar reflector.

As results from FIG. 8, the longitudinal axis of the planar reflector 8 may extend substantially parallel to the longitudinal axis of the semiconductor device 81, or perpendicular to the direction of the radiation emanating from the connection 86, respectively.

In the embodiment illustrated in FIG. 8, the optical transmitter 82 and the optical receiver 83 transmit or receive at the same frequency. If the optical transmitter 82 and the optical receiver 83 transmit or receive at different frequencies, the substantially planar reflector 84 is expediently replaced by a device that shifts the frequency of the optical signal emanating from the connection 86 to the frequency at which the optical receiver 83 receives optical signals, and subsequently transmits the optical signal shifted in its frequency back to the input/output of the connection 86.

In one embodiment, a system includes an electrical Automatic Test Equipment (ATE) to perform, with a semiconductor device to be tested which includes, in addition to the above-mentioned optical interface, an electrical interface, a self test of the semiconductor device by using the electrical interface.

The electrical ATE then controls the above-mentioned test progression and collects the results of the test that is performed, as described further above, by using the BIST logic, the optical transmitter and receiver of the semiconductor device to be tested, and the system or means for returning the optical emission from the optical transmitter to the optical receiver.

The electrical ATE may, for instance, merely have the object of a flow control and error detection device (e.g., if the above-mentioned test response signals generated in reaction to the test input signals are compared with predetermined test response signals by the semiconductor device itself, in one embodiment the BIST logic), wherein the signals required for flow control or error detection may, for instance, be exchanged between the semiconductor device and the ATE via the above-mentioned electrical interface. In one embodiment, the test response signals generated during the performing of the above-mentioned tests—also including the optical interface—may be compared with predetermined test response signals also by the electrical ATE (wherein the above-mentioned test response signals generated in reaction to the above-mentioned test input signals may, for instance, be converted to electrical signals, be transmitted to the electrical ATE via the electrical interface, and be compared with the above-mentioned predetermined test response signals by the electrical ATE).

The above-mentioned semiconductor devices illustrated in FIGS. 1 to 8 may, on principle, be any semiconductor devices with an optical interface and possibly an additional electrical interface, e.g., corresponding, integrated (analog or digital) computing circuits, and/or semiconductor memory devices such as, for instance, functional memory devices (PLAs, PALs, etc.), and table memory devices (e.g., ROMs or RAMs, in one embodiment SRAMs and DRAMs), etc.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A device for performing a test at a semiconductor device with an integrated self test function and with an optical interface comprising:
an optical transmitter; and
an optical receiver,
wherein the device comprises a system configured for returning an optical emission of the semiconductor device from the optical transmitter to the optical receiver of the semiconductor device.

2. The device of claim 1, comprising wherein the system for returning an optical emission of the semiconductor device comprise at least one reflector.

3. The device of claim 2, comprising wherein the at least one reflector substantially has the shape of a hyperboloid section.

4. The device of claim 2, wherein the at least one reflector comprises a rear reflector.

5. The device of claim 1, wherein the system for returning an optical emission of the semiconductor device comprise a fiber optic cable.

6. The device of claim 1, wherein the system for returning an optical emission of the semiconductor device further comprise at least one optical lens for beam bundling.

7. A system for performing a test comprising:
a semiconductor device with an integrated self test function and with an optical interface,
wherein the optical interface comprises an optical input and an optical output, and
wherein the system further comprises an optical system configured for returning an optical emission of the semiconductor device from the optical output of the semiconductor device to the optical input of the semiconductor device.

8. The system of claim 7, comprising wherein the semiconductor device is a memory device.

9. The system of claim 7, wherein the optical input and the optical output of the semiconductor device each comprise connections for fiber optic cables.

10. The system of claim 7, wherein the optical input and the optical output of the semiconductor device comprise a joint connection for a bi-directional fiber optic cable.

11. The system of claim 7, wherein the system for returning an optical emission of the semiconductor device comprises at least one reflector.

12. The system of claim 11, comprising wherein the at least one reflector substantially has the shape of a hyperboloid section.

13. The system of claim 11, wherein the at least one reflector comprises a rear reflector.

14. The system of claim 7, wherein the system for returning an optical emission of the semiconductor device further comprises a fiber optic cable with connections that are suited to be connected with the connections for fiber optic cables of the semiconductor device.

15. The system of claim 7, wherein the system for returning an optical emission of the semiconductor device further comprises a bi-directional fiber optic cable with at least one connection that is suited to be connected with the connection for a bi-directional fiber optic cable of the semiconductor device.

16. The system of claim 7, wherein the system for returning an optical emission of the semiconductor device further comprises at least one optical lens for beam bundling.

17. The system of claim 7, wherein the optical system for returning an optical emission of the semiconductor device further comprises a device configured for changing the frequency of the optical emission of the semiconductor device.

18. The system of claim 7, wherein the semiconductor device further comprises an electrical interface.

19. The system of claim 18, wherein the system further comprises an automatic electrical test equipment that is connected with the electrical interface of the semiconductor device.

20. The system of claim 18, wherein the optical system further comprises a device for returning an electrical output signal of the semiconductor device from an output of the electrical interface to an input of the electrical interface.

21. A method for performing a test at a semiconductor device with an integrated self test function and with an optical interface comprising:
providing an optical input;
providing an optical output, and
returning an optical emission of the semiconductor device from the optical output to the optical input of the semiconductor device.

22. The method of claim 21, comprising returning the optical emission of the semiconductor device from the optical output to the optical input of the semiconductor device via at least one reflector, fiber optic cable, or optical lens.

23. A method for performing a test at a semiconductor device with an integrated self test function and with an optical interface comprising:
providing an optical input;
providing an optical output,
returning an optical emission of the semiconductor device from the optical output to the optical input of the semiconductor device;
generating a plurality of test input data for a partial circuit to be tested by using the integrated self test function;
converting of test output data generated by the partial circuit to be tested to the optical emission;
emitting the optical emission via the optical output of the semiconductor device;
converting the optical emission returned to the optical input of the semiconductor device to electrical data signals; and
comparing the electrical data signals with predetermined test response data by using the integrated self test function.

24. A device for performing a test at a semiconductor device with an integrated self test function and with an optical interface comprising:
an optical transmitter; and
an optical receiver,
wherein the device comprises means for returning an optical emission of the semiconductor device from the optical transmitter to the optical receiver of the semiconductor device.

25. The device of claim 24, comprising wherein the means for returning an optical emission of the semiconductor device comprise at least one reflector.
